(19) United States
(12) Patent Application Publication
(10) Pub. No.: US 2026/0293352 A1
(43) Pub. Date: Sep. 24, 2026

(54) IMAGE SENSOR INCLUDING BACKSIDE SCATTERING STRUCTURE

(71) Applicant: Samsung Electronics Co., Ltd., Suwon-si (KR)

(72) Inventors: Younggu Jin, Suwon-si (KR); Sungyoung Seo, Suwon-si (KR); Minhee Son, Suwon-si (KR); Youngsun Oh, Suwon-si (KR); Seungjoon Lee, Suwon-si (KR); Seunghyun Lee, Suwon-si (KR); Sunghyuck Cho, Suwon-si (KR)

(73) Assignee: Samsung Electronics Co., Ltd., Suwon-si (KR)

(21) Appl. No.: 19/572,213

(22) Filed: Mar. 19, 2026

(30) Foreign Application Priority Data
Mar. 20, 2025 (KR) 10-2025-0036215

(51) Int. Cl. H10F 39/00

(52) U.S. Cl. CPC H10F 39/807; H10F 39/8063

(57) ABSTRACT

An image sensor includes a substrate including first to fourth photodiode regions, a first isolation layer formed to surround the first to fourth photodiode regions, a second isolation layer formed to protrude from the first isolation layer and separating the first to fourth photodiode regions, a floating diffusion region formed on the first surface and in which photocharges formed in a photodiode of each of the first to fourth photodiode regions accumulate, a backside scattering structure formed inside a trench formed in the second surface of the substrate, and at least one micro-lens, wherein respective gates of first to fourth transfer transistors are electrically connected to one another, the second isolation layer is formed to expose a central region of the first to fourth photodiode regions, and the floating diffusion region is arranged in the central region of the first to fourth photodiode regions.

### CROSS-REFERENCE TO RELATED APPLICATIONS

This present application claims priority to and the benefit under 35 USC § 119(a)-(d) of Korean Patent Application No. 10-2025-0036215, filed on Mar. 20, 2025, in the Korean Intellectual Property Office, the entire disclosure of which is incorporated herein by reference.

### FIELD

The present disclosure provides and image sensor and more particularly to an image sensor including a backside scattering structure.

### BACKGROUND

Image sensors, which capture images and convert the captured images into electrical signals, have been used in consumer electronics, such as digital cameras, cameras for mobile phones, and portable camcorders, as well as cameras mounted in vehicles, security devices, and robots.

In recent years, the importance of light detection capabilities in the near-infrared range has increased significantly due to the demand for various image sensors, such as iris scanners, security cameras, and time-of-flight (ToF) sensors. To increase infrared sensitivity, image sensors may be required to increase the incident distance of light to a photoelectric conversion device (e.g., a photodiode).

### SUMMARY

According to aspects of the disclosed concepts, there is provided an image sensor including a substrate including first to fourth photodiode regions in which a photodiode is respectively formed, a first isolation layer formed to surround the first to fourth photodiode regions and penetrating from a first surface of the substrate to a second surface of the substrate that is opposite to the first surface, a second isolation layer formed to protrude from the first isolation layer and separating the first to fourth photodiode regions, a floating diffusion region formed on the first surface and in which photocharges generated in the photodiode of each of the first to fourth photodiode regions accumulate, at least one backside scattering structure formed inside a trench formed on the second surface of the substrate, and at least one micro-lens placed on the second surface of the substrate, wherein respective gates of first to fourth transfer transistors are electrically connected to one another, the second isolation layer is formed to expose a central region of the first to fourth photodiode regions, and the floating diffusion region is arranged in the central region of the first to fourth photodiode regions.

According to aspects of the disclosed concepts, there is provided an image sensor including a substrate including first to fourth photodiode regions in which a photodiode is respectively formed, an isolation layer separating the first to fourth photodiode regions and penetrating from a first surface of the substrate to a second surface of the substrate that is opposite to the first surface, a floating diffusion region formed on the first surface and in which photocharges generated in the photodiode of each of the first to fourth photodiode regions accumulate, first to fourth transfer transistors transferring photocharges generated in the photodiode of each of the first to fourth photodiode regions to the floating diffusion region, at least one micro-lens placed on the second surface of the substrate, and at least one backside scattering structure formed inside a trench formed on the second surface of the substrate and positioned to correspond to a center of the at least one micro-lens, wherein respective gates of the first to fourth transfer transistors are electrically connected to one another.

According to aspects of the disclosed concepts, there is provided an image sensor including a substrate including first to fourth photodiode regions in which a photodiode is respectively formed, a isolation layer separating the first to fourth photodiode regions and penetrating from a first surface of the substrate to a second surface of the substrate that is opposite to the first surface, a floating diffusion region formed on the first surface and in which photocharges generated in the photodiode of each of the first to fourth photodiode regions accumulate, first to fourth transfer transistors transferring photocharges generated in the photodiode of each of the first to fourth photodiode regions to the floating diffusion region, a color filter layer and a micro-lens arranged on the second surface of the substrate, and a backside scattering structure placed between the substrate and the color filter layer on the second surface of the substrate, wherein respective gates of the first to fourth transfer transistors are electrically connected to one another.

According to aspects of the disclosed concepts, there is provided a method for manufacturing an image sensor including providing a substrate including first to fourth photodiode regions in which a photodiode is respectively formed, forming a first isolation layer to surround the first to fourth photodiode regions and penetrate from a first surface of the substrate to a second surface of the substrate that is opposite to the first surface, forming a second isolation layer to protrude from the first isolation layer and separate the first to fourth photodiode regions, forming a floating diffusion region on the first surface and in which photocharges generated in the photodiode of each of the first to fourth photodiode regions accumulate, forming at least one backside scattering structure inside a trench formed on the second surface of the substrate, and placing at least one micro-lens on the second surface of the substrate, wherein respective gates of first to fourth transfer transistors are electrically connected to one another, the second isolation layer is formed to expose a central region of the first to fourth photodiode regions, and the floating diffusion region is arranged in the central region of the first to fourth photodiode regions.

### BRIEF DESCRIPTION OF THE DRAWINGS

Embodiments will be more clearly understood from the following detailed description taken in conjunction with the accompanying drawings in which:

FIG. 1 is a block diagram illustrating an image sensor according to embodiments;

FIGS. 2A and 2B are circuit diagrams of pixels included in a pixel array of FIG. 1;

FIGS. 3 and 4 are diagrams of pixels included in an image sensor according to embodiments;

FIGS. 5A and 5B are diagrams of pixels included in an image sensor according to the disclosed concepts and are cross-sectional views taken along line I-I′ of FIGS. 3 and 4;

FIG. 6 is a diagram of pixels included in an image sensor according to embodiments;

FIG. 7 is a diagram of pixels included in an image sensor according to embodiments;

FIGS. 8 and 9 are diagrams of pixels included in an image sensor according to embodiments;

FIGS. 10 and 11 are diagrams of pixels included in an image sensor according to embodiments;

FIGS. 12 and 13 are diagrams of pixels included in an image sensor according to embodiments;

FIG. 14 is a diagram of pixels included in an image sensor according to embodiments; and

FIG. 15 is a diagram of pixels included in an image sensor according to embodiments.

### DETAILED DESCRIPTION

Hereinafter, embodiments are described in detail with reference to the accompanying drawings. Herein, the X-axis direction may be referred to as a first horizontal direction parallel to a main surface of a substrate, and the Y-axis direction may be referred to as a second horizontal direction parallel to the main surface of the substrate.

The disclosed concepts relate to an image sensor, and more particularly, to an image sensor including a backside scattering structure.

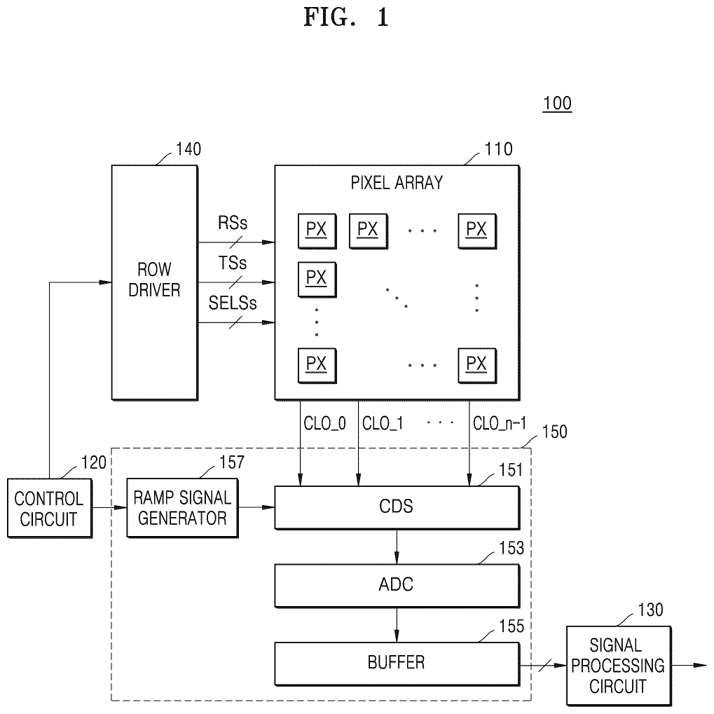

FIG. 1 is a block diagram illustrating an image sensor 100 according to embodiments.

Referring to FIG. 1, the image sensor 100 may include a pixel array 110, a control circuit 120, a signal processing circuit 130, a row driver 140, and a read-out circuit 150. The read-out circuit 150 may include a correlated double sampler (CDS) 151, an analog-to-digital converter (ADC) 153, and a buffer 155.

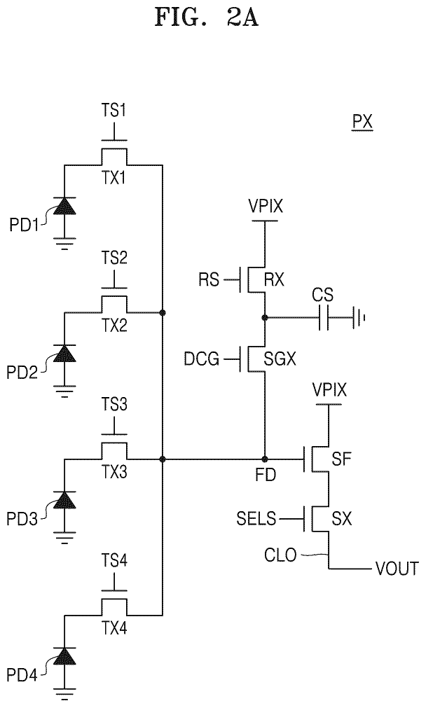

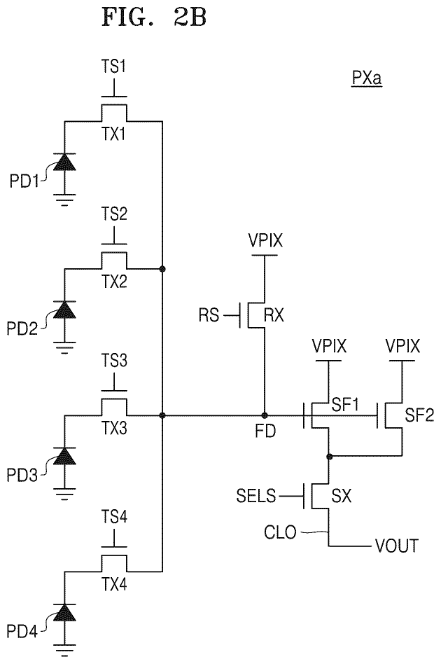

The pixel array 110 converts an optical signal into an electrical signal and may include a plurality of pixels PX arranged two-dimensionally. Each pixel PX included in the pixel array 110 may generate pixel signals according to the intensity of detected light, may be implemented as a photoelectric conversion device, such as, for example, a charge-coupled device (CCD) or a complementary metal oxide semiconductor (CMOS), and may also be implemented as various types of photoelectric conversion devices. In embodiments, the pixel PX may include a plurality of photoelectric conversion devices that transfer generated photocharges to a single floating diffusion region (e.g., FD of FIG. 2A).

The pixel array 110 may include a color filter to sense various colors, and each of the plurality of pixels PX may sense a corresponding color. For example, the pixel PX may include a corresponding one of a red color filter, a green color filter, and a blue color filter. Alternatively, for example, the pixel PX may include at least one of a yellow color filter, a cyan color filter and a magenta color filter, or the pixel PX may be configured to sense all visible light.

In addition, the pixel array 110 may detect infrared rays, while detecting visible light of various colors. In embodiments, each of the plurality of pixels PX included in the pixel array 110 may include at least one backside scattering structure. The at least one backside scattering structure may include a material (either a low refractive index material or a high refractive index material) having a different refractive index than a component nearby. In embodiments, the backside scattering structure may be formed in a trench within a substrate or may be formed on the substrate in the form of a prism. Incident light incident on the pixel array 110 may be scattered by a plurality of backside scattering structures included in the pixel array 110, thereby increasing a path of the incident light, and thus, increasing infrared sensitivity of the image sensor 100.

Each of the plurality of pixels PX may output a pixel signal to the CDS 151 through a corresponding column output line among first to n-th column output lines CLO_0 to CLO_n−1. The CDS 151 may sample and hold a pixel signal provided from the pixel array 110. The CDS 151 may double-sample a level of specific noise and a level according to the pixel signal and output a level corresponding to the difference therebetween. In addition, the CDS 151 may receive ramp signals generated by a ramp signal generator 157, compare the ramp signals with one another, and output a comparison result.

The ADC 153 may convert an analog signal corresponding to a level received from the CDS 151 into a digital signal. The buffer 155 may latch the digital signal, and the latched digital signal may be sequentially output to the signal processing circuit 130 or image data may be output to the outside of the image sensor 100.

The control circuit 120 may control the row driver 140 to cause the pixel array 110 to absorb light and accumulate a charge or temporarily store the accumulated charge and output an electrical signal according to the stored charge to the outside of the pixel array 110. In addition, the control circuit 120 may control the read-out circuit 150 to measure the level of the pixel signal provided from the pixel array 110.

The row driver 140 may generate control signals RSs, TSs, and SELSs for controlling the pixel array 110 and provide the control signals RSs, TSs, and SELSs to the plurality of pixels PX. The row driver 140 may determine activation and deactivation timing of reset control signals RSs, transmission control signals TSs, and selection signals SELSs provided to the pixels PXs.

The signal processing circuit 130 may perform signal processing on a signal output from the buffer 155. In embodiments, the signal processing circuit 130 may perform an image processing operation including a remosaic processing operation on data received from the read-out circuit 150. In embodiments, the signal processing circuit 130 may perform signal processing, such as noise reduction processing, gain adjustment, waveform shaping processing, interpolation processing, white balance processing, gamma processing, edge enhancement processing, and the like. However, in embodiments, the signal processing circuit 130 may be provided in a processor outside the image sensor 100.

FIGS. 2A and 2B are circuit diagrams of the pixels PX included in the pixel array 110 of FIG. 1.

Referring to FIG. 2A, the pixel PX may include a plurality of photoelectric conversion devices, for example, first to fourth photodiodes PD1 to PD4. Each of the first to fourth photodiodes PD1 to PD4 may generate a photocharge that varies depending on the intensity of light. For example, each of the first to fourth photodiodes PD1 to PD4 is a P-N junction diode that may generate charges, i.e., electrons (negative charges) and holes (positive charges), in proportion to the quantity of incident light. Each of the first to fourth photodiodes PD1 to PD4 is an example of a photoelectric conversion device and may be at least one of a phototransistor, a photogate, a pinned photodiode (PPD), and combinations thereof.

FIGS. 2A and 2B illustrate an example in which four photoelectric conversion devices, that is, first to fourth photodiodes PD1 to PD4, are included in one pixel PX, but the disclosed concepts is not limited thereto. The pixel PX may include four or more photoelectric conversion devices.

The pixel PX may include a plurality of transfer transistors, for example, first to fourth transfer transistors TX1 to TX4, respectively corresponding to a plurality of photoelectric conversion devices. Each of the first to fourth transfer transistors TX1 to TX4 may transfer the generated photocharge to a floating diffusion region FD according to a transmission control signal (a corresponding one of TS1 to TS4). When each of the first to fourth transfer transistors TX1 to TX4 is turned on, photocharges generated in the corresponding photodiode among the first to fourth photodiodes PD1 to PD4 may be transferred to one floating diffusion region FD and accumulated and stored in the floating diffusion region FD.

In embodiments, first to fourth transmission control signals TS1 to TS4 provided to the first to fourth transfer transistors TX1 to TX4 may be the same signal. In embodiments, the respective gates of the first to fourth transfer transistors TX1 to TX4 may be electrically connected to one another. Therefore, the first to fourth transfer transistors TX1 to TX4 may transfer photocharges formed in the first to fourth photodiodes PD1 to PD4 to the floating diffusion region FD at the same time. Accordingly, the first to fourth photodiodes PD1 to PD4 may operate as a single photoelectric conversion device, the full well capacity (FWC) of the photoelectric conversion device may be increased, and the dynamic range characteristics of the image sensor may be improved.

The pixel PX may include a reset transistor RX, which may periodically reset charges accumulated in the floating diffusion region FD. When the reset transistor RX is turned on according to a reset control signal RS provided from the row driver (e.g., 140 of FIG. 1), charges accumulated in the floating diffusion region FD may be discharged so that the floating diffusion region FD may be reset (e.g., reset to the power supply voltage VPIX level).

In addition, the reset transistor RX may reset the capacitor CS (e.g., to the power supply voltage VPIX level) according to the reset control signal RS. That is, the reset transistor RX may be turned on in response to the reset control signal RS applied to the gate, thereby resetting the floating diffusion region FD or capacitor CS based on the power supply voltage VPIX. For example, a storage control transistor SGX may be turned on together with the reset transistor RX in response to a conversion gain control signal DCG received by the gate, so that the power supply voltage VPIX is applied to the floating diffusion region FD and the floating diffusion region FD may be reset.

The capacitor CS may be a passive element having fixed or variable capacitance, may be a capacitor formed by or connected to a source/drain of the storage control transistor SGX, or a parasitic capacitor formed by another pixel that may be connected to the source/drain of the storage control transistor SGX.

Because each of the first to fourth photoelectric conversion devices PD1 to PD4 generates a charge according to the light intensity, the amount of charge generated by the first to fourth photodiodes PD1 to PD4 may vary depending on an image capturing environment (low light or high light). For example, in a high-light environment, the amount of charge generated in the first photodiode PD1 may reach the FWC of the first photoelectric conversion device PD1, but in a low-light environment, this may not be the case.

The charges accumulated in the floating diffusion region FD may be converted into a voltage in the floating diffusion region FD. A conversion gain (a unit of the conversion gain may be, for example, uV/e) is determined by capacitance of the floating diffusion region FD and may be inversely proportional to the capacitance of the floating diffusion region FD. Increasing the capacitance of the floating diffusion region FD may decrease the conversion gain, and decreasing the capacitance thereof may increase the conversion gain.

The storage control transistor SGX may be turned on or off based on the conversion gain control signal DCG received by the gate thereof, and when the storage control transistor SGX is turned on, the capacitor CS may be connected to the floating diffusion region FD, and the floating diffusion region FD may have parasitic capacitance and capacitance due to the capacitor CS, and accordingly, the total capacitance of the floating diffusion region FD may increase.

The conversion gain when the storage control transistor SGX is turned off may be higher than the conversion gain when the storage control transistor SGX is turned on. When the storage control transistor SGX is turned off, it may be referred to as a high conversion gain (HCG) mode, and when the storage control transistor SGX is turned on, it may be referred to as a low conversion gain (LCG) mode.

In this manner, the pixel PX may operate in either the HCG mode or LCG mode depending on the turn-on and turn-off of the storage control transistor SGX. In low light, the pixel PX may operate in the HCG mode, and the low light detection performance of the image sensor (e.g., 100 in FIG. 1) may be improved. On the other hand, in high light, the pixel PX may operate in the LCG mode, and because the capacitance of the floating diffusion region FD of the pixel PX is large, the FWC may increase. Accordingly, the high light detection performance of the image sensor 100 may be improved. In addition, the image sensor 100 may provide dual conversion gain and sense low-amount light and high-amount light, so that the dynamic range of the image sensor 100 may be expanded (or increased). The pixel PX providing the DCG described with reference to FIG. 2A is an example, and the configuration of the pixel PX may be modified in various manners.

An amplifying transistor SF may be controlled depending on the amount of photocharges accumulated in the floating diffusion region FD. The amplifying transistor SF may function as a buffer amplifier to buffer a signal according to the charge stored in the floating diffusion region FD and may be a source follower. The amplifying transistor SF may amplify a potential change in the floating diffusion region FD and output the same as a pixel signal VOUT to a column output line CLO, for example, one of CLO_0 to CLO_n−1 in FIG. 1). A selection transistor SX may output the pixel signal VOUT to CDS (e.g., 151 in FIG. 1) through the column output line CLO in response to a selection signal SELS.

Referring to FIG. 2B, a pixel PXa included in the pixel array 110 of FIG. 1 may include first to fourth photodiodes PD1 to PD4, first to fourth transfer transistors TX1 to TX4, a reset transistor RX, and a selection transistor SX, and the pixel PXa may include a plurality of amplifying transistors, for example, a first amplifying transistor SF1 and a second amplifying transistor SF2. The power supply voltage VPIX is applied to one terminal of each of the first amplifying transistor SF1 and the second amplifying transistor SF2, and the other terminal of each of the first amplifying transistor SF1 and the second amplifying transistor SF2 may be connected to the selection transistor SX. Both the first amplifying transistor SF1 and the second amplifying transistor SF2 may operate simultaneously and generate a pixel signal VOUT according to the voltage of the floating diffusion region FD. Because the first amplifying transistor SF1 and the second amplifying transistor SF2 of the pixel PXa operate as one amplifying transistor, a pixel signal VOUT may be stably generated.

Alternatively, unlike as shown in FIGS. 2A and 2B, the pixel (PX or PXa) may include a plurality of selection transistors that act as a single selection transistor.

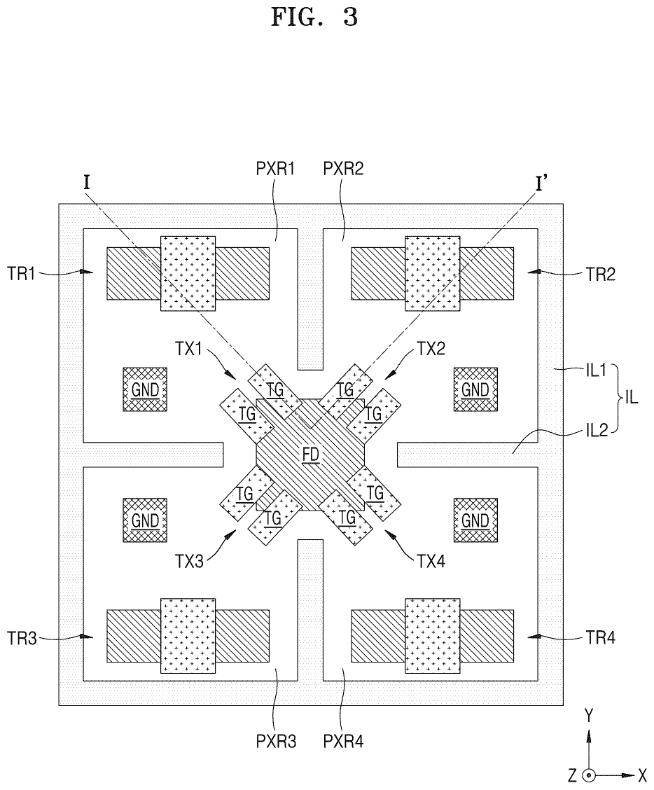

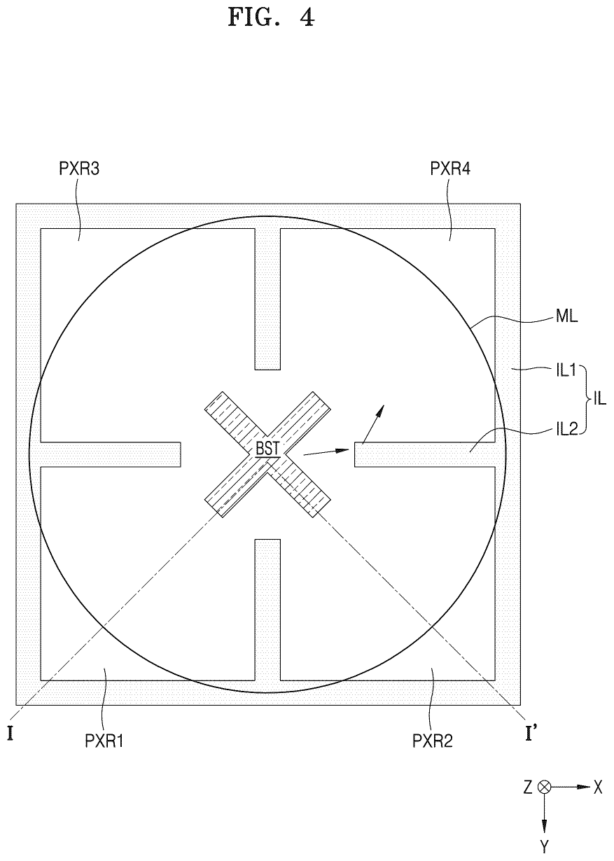

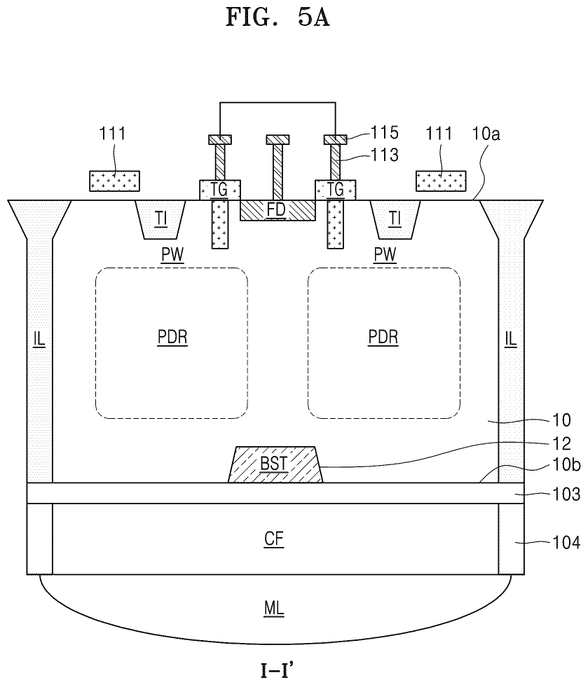

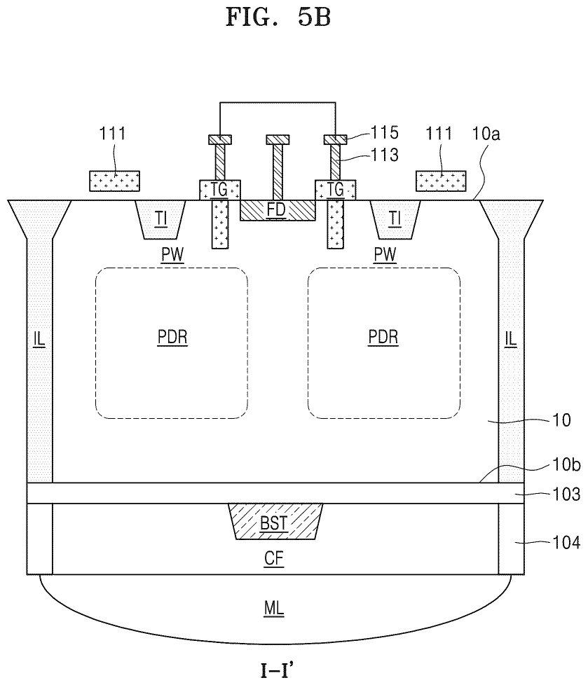

FIGS. 3 and 4 are diagrams of pixels included in an image sensor according to embodiments. FIG. 3 is a layout viewed in a direction (a-Z-axis direction) from a first surface (a front surface) of a substrate (e.g., 10 in FIG. 5A) toward a second surface (a rear surface), and FIG. 4 is a layout viewed in a direction (a Z-axis direction) from the second surface (the rear surface) of the substrate 10 toward the first surface (the front surface) thereof.

Referring to FIG. 3, a pixel may be formed on the substrate and may include four photodiode regions, i.e., first to fourth photodiode regions PXR1 to PXR4, arranged in two rows and two columns (2×2) in the X-axis direction and the Y-axis direction. A photoelectric conversion device (e.g., PD1 to PD4 of FIGS. 2A and 2B) may be formed in each of the first to fourth photodiode regions PXR1 to PXR4.

In addition, a ground contact GND to which a ground voltage is applied may be placed in each of the first to fourth photodiode regions PXR1 to PXR4. A ground voltage may be applied to one end of a photoelectric conversion device formed in each of the first to fourth photodiode regions PXR1 to PXR4 through a ground contact GND.

In each of the first to fourth photodiode regions PXR1 to PXR4, a corresponding transfer transistor among the first to fourth transfer transistors TX1 to TX4 may be placed. The first to fourth transfer transistors TX1 to TX4 may transfer photocharges formed in the photoelectric conversion devices of each of the first to fourth photodiode regions PXR1 to PXR4 to the floating diffusion region FD.

In embodiments, each of the first to fourth transfer transistors TX1 to TX4 may include a plurality of gate lines electrically connected to one another and may include vertical-type buried gate lines (dual vertical type). In embodiments, the respective gates of the first to fourth transfer transistors TX1 to TX4 may be electrically connected to one another. Therefore, the first to fourth transfer transistors TX1 to TX4 may transfer the photocharges formed in the photoelectric conversion devices of the first to fourth photodiode regions PXR1 to PXR4 to the floating diffusion region FD at the same point in time and for the same period of time.

A corresponding transistor among the first to fourth transistors TR1 to TR4 may be placed in each of the first to fourth photodiode regions PXR1 to PXR4. For example, each of the first to fourth transistors TR1 to TR4 may be one of the reset transistor RX, the amplifying transistor SF, the selection transistor SX, and the storage control transistor SGX described above with reference to FIG. 2A. Alternatively, for example, each of the first to fourth transistors TR1 to TR4 may be one of the reset transistor RX, the amplifying transistor SF, the first selection transistor SX1, and the second selection transistor SX2 described above with reference to FIG. 2B.

A pixel may be separated from other pixels by an isolation layer IL (or a deep trench isolation), and first to fourth photodiode regions PXR1 to PXR4 included in the pixel may be distinguished from one another by the isolation layer IL. For example, the isolation layer IL may include a first isolation layer IL1 formed to surround the first to fourth photodiode regions PXR1 to PXR4 and a second isolation layer IL2 that separates the first to fourth photodiode regions PXR1 to PXR4, respectively. Here, the second isolation layer IL2 may be formed to protrude from the first isolation layer IL1 in the X-axis direction, the-X-axis direction (reverse direction of the X-axis direction), the Y-axis direction, and the-Y-axis direction (reverse direction of the Y-axis direction). The X-axis direction and the Y-axis direction may be parallel to a main surface of the substrate and may be perpendicular to one another.

The second isolation layer IL2 may be formed to expose a central region of the first to fourth photodiode regions PXR1 to PXR4, and the floating diffusion region FD may be formed in the exposed central region thereof. Photocharges formed in the photoelectric conversion device of each of the first to fourth photodiode regions PXR1 to PXR4 may accumulate in the floating diffusion region FD. Accordingly, the FWC of the photoelectric conversion device formed in each of the first to fourth photodiode regions PXR1 to PXR4 may be increased, and an image sensor with a high dynamic range may be implemented.

Referring to FIG. 4, an image sensor may include a micro-lens ML. In embodiments, one micro-lens ML may be placed on the first to fourth photodiode regions PXR1 to PXR4. Incident light passing through the micro-lens ML may be focused inside the pixel.

A pixel of the image sensor may include a backside scattering structure BST. The backside scattering structure BST may increase a path of incident light provided to the image sensor, thereby increasing the infrared sensitivity. For example, the backside scattering structure BST may include a material having a different composition and refractive index from a nearby configuration, and thus, incident light may be scattered by the backside scattering structure BST, and scattered light may be provided to the photoelectric conversion devices of the first to fourth photodiode regions PXR1 to PXR4.

In embodiments, the backside scattering structure BST may be positioned to correspond to the center of the micro-lens ML. Accordingly, incident light passing through the micro-lens ML may be refracted and incident on the backside scattering structure BST, and light scattered by the backside scattering structure BST may be provided into each of the first to fourth photodiode regions PXR1 to PXR4.

The backside scattering structure BST may be formed to have an ‘X’ shape. For example, the backside scattering structure BST may include a first pattern extending in a third horizontal direction, that is, a diagonal direction, in which the X-axis direction (the first horizontal direction) and the Y-axis direction (the second horizontal direction) intersect, and a second pattern extending in a fourth horizontal direction, and the first pattern may be formed to intersect with the second pattern. Accordingly, light incident on the backside scattering structure BST may be scattered by the backside scattering structure BST and then scattered again by the isolation layer IL (for example, the second isolation layer IL2) to be provided into the interior of the first to fourth photodiode regions PXR1 to PXR4, and the path of light (particularly, infrared light) incident on the photoelectric conversion device may be lengthened.

FIGS. 5A and 5B are diagrams of pixels included in an image sensor according to the disclosed concepts, and are cross-sectional views taken along line I-I′ of FIGS. 3 and 4.

Referring to FIGS. 3, 4, and 5A, the image sensor (e.g., 100 of FIG. 1) is provided with the substrate 10. The substrate 10 may include a plurality of pixels (e.g., PX of FIG. 1) arranged two-dimensionally in the first horizontal direction (the X-axis direction) and the second horizontal direction (the X-axis direction) that intersect one another.

The substrate 10 may include a first surface 10a and a second surface 10b that are opposite to one another. Incident light may be incident into the substrate 10 through the second surface 10b. The substrate 10 may be a single crystal wafer, an epitaxial layer, or a silicon on insulator (SOI) substrate including silicon and/or germanium. The substrate 10 may be doped with second conductivity-type impurities. The second conductivity type may be, for example, P type. The second conductivity-type impurities may be, for example, boron.

The first isolation layer IL1 that separates and limits the plurality of pixels PX from one another may be placed within the substrate 10. The first isolation layer IL1 may have a mesh shape in a planar view. In addition, the second isolation layer IL2 may be arranged within the substrate 10 to separate a plurality of photodiode regions included in the pixel PX, i.e., the first to fourth photodiode regions PXR1 to PXR4 from one another. The isolation layer IL including the first isolation layer IL1 and the second isolation layer IL2 may be defined as a deep trench isolation film formed within the substrate 10. The isolation layer IL may be formed to penetrated from the first surface 10a of the substrate 10 to the second surface 10b of the substrate 10. For example, the isolation layer IL may be a front-side deep trench isolation (FDTI) film formed by etching from the first surface 10a of the substrate 10 toward the second surface 10b thereof. In embodiments, the isolation layer IL may be formed to have a cross-sectional width narrowing from the first surface 10a to the second surface 10b.

In embodiments, the isolation layer IL may include an isolation conductive pattern, an isolation insulating pattern, and a buried insulating pattern. However, without being limited thereto, the isolation layer IL may not include the isolation conductive pattern.

The isolation conductive pattern of the isolation layer IL may be apart from the substrate 10, and the isolation conductive pattern may include a conductive material having a different refractive index from that of the substrate 10. For example, the isolation conductive pattern may include polysilicon or metal doped with impurities. In embodiments, a lower voltage (e.g., a negative voltage) is applied to the isolation conductive pattern than a photoelectric conversion region PDR, thereby increasing the energy barrier between the isolation conductive pattern and the photoelectric conversion region PDR to reduce a dark current. Accordingly, the reliability of the image sensor may be improved.

The isolation insulating pattern of the isolation layer IL may be arranged between the isolation conductive pattern of the isolation layer IL and the substrate 10, and the buried insulating pattern of the isolation layer IL may be arranged below the isolation conductive pattern. The isolation insulating pattern may be located between the buried insulating pattern and the substrate 10. The isolation insulating pattern and the buried insulating pattern may include an insulating material having a different refractive index from that of the substrate 10. For example, the isolation insulating pattern and the buried insulating pattern may each include silicon oxide.

The photoelectric conversion region PDR may be placed inside the substrate 10. A well region PW may be placed between the photoelectric conversion region PDR and the first surface 10a. The well region PW may be doped with, for example, second conductivity-type (P-type) impurities doped into the substrate 10. A concentration of the second conductivity-type impurities doped in the well region PW may be equal to or greater than a concentration of the impurities doped in the substrate 10.

The photoelectric conversion region PDR may be doped with the first conductivity-type impurities that are opposite to the second conductivity-type impurities. For example, the photoelectric conversion region PDR may be doped with N-type impurities, such as phosphorus or arsenic. An N-type impurity region of the photoelectric conversion region PDR may form a P-N junction with a P-type impurity region of the nearby substrate 10 and/or the well region PW to form a photodiode, and when light is incident, electron-hole pairs may be generated by the P-N junction.

A separator TI for isolating the active regions of the transistors constituting the pixel PX from one another may be placed adjacent to the first surface 10a of the substrate 10. The separator TI may be formed by a shallow trench isolation (STI) method and may be formed as a single film or multi-film structure of at least one of a silicon oxide film, a silicon nitride film, and a silicon oxynitride film. Alternatively, the separator TI may be formed by doping the first conductivity-type impurities which are the same as those doped into the substrate 10 and may have a doping concentration that is higher than a doping concentration of the impurities doped into the substrate 10. The first isolation layer IL1 and the second isolation layer IL2 may be formed on the separator TI.

A gate insulating film may be placed between a gate 111 of each of the first to fourth transistors TR1 to TR4 and the substrate 10. The gate insulating film may include a single film or multi-films of at least one of silicon oxide, a metal oxide, a silicon nitride film, and a silicon oxynitride film.

In embodiments, the gate TG of each of the first to fourth transfer transistors TX1 to TX4 may be a vertical-type buried gate line. For example, a portion of the gate TG of each of the first to fourth transfer transistors TX1 to TX4 may be inserted into the substrate 10. Alternatively, in embodiments, the gate TG of each of the first to fourth transfer transistors TX1 to TX4 may be a planar-type gate. The gate insulating film may be placed between the gate TG of each of the first to fourth transfer transistors TX1 to TX4 and the substrate 10.

The floating diffusion region FD may be arranged in an active region of the gate TG of each of the first to fourth transfer transistors TX1 to TX4. The floating diffusion region FD may be doped with first conductivity-type impurities that are opposite to the second conductivity-type impurities doped into the substrate 10. For example, the floating diffusion region FD may be doped with N-type impurities, such as phosphorus or arsenic.

On the first surface 10a, a plurality of interlayer insulating films may be sequentially stacked, and the plurality of interlayer insulating films may have a single-film or multi-film structure of at least one of, for example, silicon oxide, silicon nitride, silicon oxynitride, and a porous insulator.

An interconnection layer 115 may be placed between different interlayer insulating films, and a via/contact 113 may be placed to penetrate the interlayer insulating film and be connected to the interconnection layer 115. In embodiments, the gates TG of the first to fourth transfer transistors TX1 to TX4 may be electrically connected to one another through the interconnection layer 115 and the via/contact 113.

A trench 12 may be formed in the second surface 10b of the substrate 10, and a backside scattering structure BST may be formed in the trench 12. In embodiments, the backside scattering structure BST may be formed by forming the trench 12 in the second surface 10b of the substrate 10 and then filling the inside of the trench 12 with at least one material for forming an anti-reflective layer 103. The backside scattering structure BST may include the same material as that of the anti-reflective layer 103.

In embodiments, the backside scattering structure BST may include a material having a lower refractive index than a nearby configuration, and the backside scattering structure BST may include a material having a lower refractive index than that of the substrate 10. For example, the substrate 10 may include silicon, and the backside scattering structure BST may include titanium oxide, hafnium oxide, or silicon oxide.

The anti-reflective layer 103 may be placed on the second surface 10b of the substrate 10. The anti-reflective layer 103 may adjust the refractive index to suppress reflection of incident light and secure high transmittance. The anti-reflective layer 103 may prevent reflection of incident light so that the incident light may smoothly reach the photoelectric conversion portion PDR through a color filter CF. For example, a refractive index of the anti-reflective layer 103 may be 2.0 or more and 2.5 or less, but is not limited thereto. The material and thickness of the anti-reflective layer 103 may vary depending on the wavelength of the incident light. For example, the anti-reflective layer 103 may be a single layer or a multilayer. The anti-reflective layer 103 may include, for example, silicon oxide, silicon nitride, silicon oxynitride, hafnium oxide, aluminum oxide, or titanium oxide. The anti-reflective layer 103 may be referred to as a bottom anti-reflective layer (BARL) in the sense that the anti-reflective layer 103 is formed below the micro-lens ML and the color filter CF layer on which light is incident.

A grid pattern 104 may be formed on the anti-reflective layer 103. For example, the grid pattern 104 may include a light-blocking pattern and a low refractive index pattern that are sequentially stacked. The light-blocking pattern and the low refractive index pattern may planarly have a mesh shape and may overlap the first isolation layer IL1, and the light-blocking pattern and the low refractive index pattern may expose the anti-reflective layer 103 on the photoelectric conversion portion PDR.

The color filter CF may be placed on the anti-reflective layer 103, and the micro-lens ML may be placed on the color filter CF. The color filter CF may be, for example, one of a red color filter, a green color filter, and a blue color filter. The micro-lens ML may focus incident light and provide the same to the backside scattering structure BST.

Referring to FIGS. 3, 4, and 5B, the image sensor 100 may include the backside scattering structure BST disposed on the second surface 10b of the substrate 10. The backside scattering structure BST may be placed between the anti-reflective layer 103 and the color filter CF. For example, the image sensor 100 according to the disclosed concepts may be manufactured by forming the anti-reflective layer 103 on the second surface 10b of the substrate 10, forming the backside scattering structure BST having a nano prism structure on the anti-reflective layer 103, and then forming the color filter CF on the backside scattering structure BST and forming the micro-lens ML.

In embodiments, the backside scattering structure BST may include a material with a higher refractive index than a nearby structure, for example, a material with a higher refractive index than that of the color filter CF. For example, the backside scattering structure BST may include titanium oxide, amorphous silicon, or polysilicon.

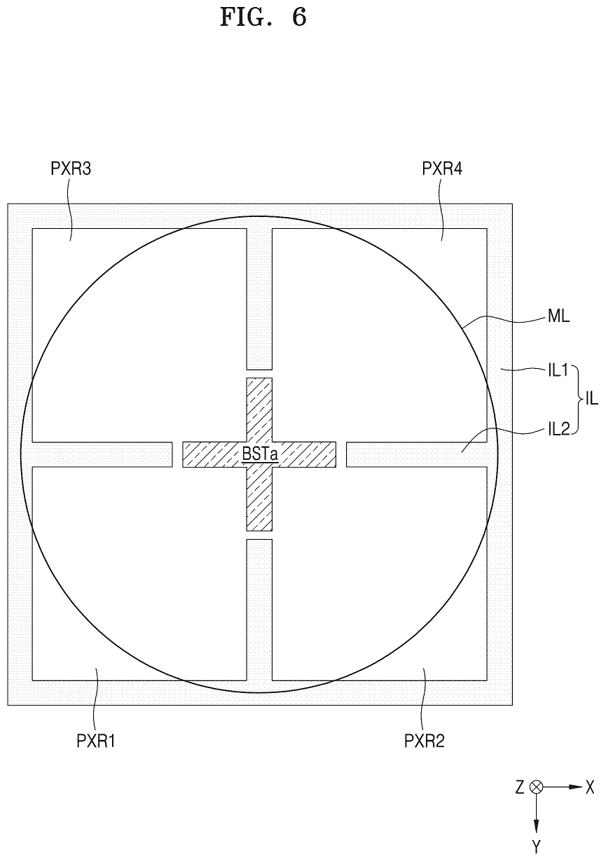

FIG. 6 is a diagram of pixels included in an image sensor according to embodiments. FIG. 6 is a layout viewed in a direction (a Z-axis direction) from the second surface (the back surface) of the substrate toward the first surface (the front surface) thereof. In the description of FIG. 6, redundant descriptions of the same reference numerals as those in FIG. 4 are omitted.

Referring to FIG. 6, a pixel of an image sensor may include a backside scattering structure BSTa comprising a material having a different composition and refractive index from the surroundings. In embodiments, a backside scattering structure BSTa may be positioned to correspond to the center of the micro-lens ML. Incident light passing through the micro-lens ML may be refracted and incident on the backside scattering structure BSTa, and light scattered by the backside scattering structure BSTa may be provided into each of the first to fourth photodiode regions PXR1 to PXR4.

The backside scattering structure BSTa may be formed to have a ‘+’ shape. For example, the backside scattering structure BSTa may have a shape in which the first pattern extending in the X-axis direction and the second pattern extending in the Y-axis direction intersect one another. That is, the backside scattering structure BSTa may include patterns extending in the same direction as the direction in which the second isolation layer IL2 extends.

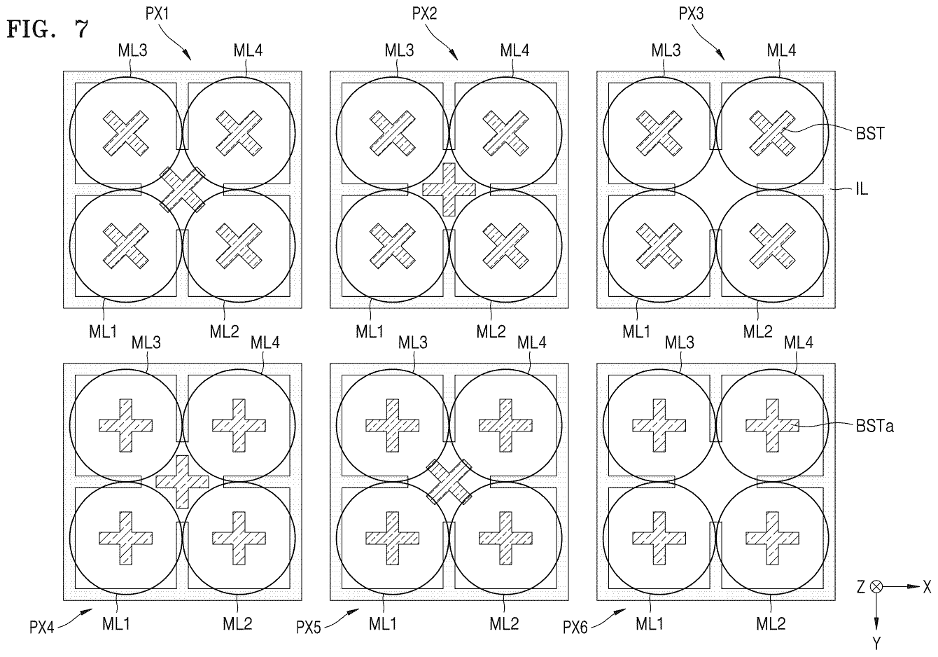

FIG. 7 is a diagram of pixels included in an image sensor according to embodiments. FIG. 7 is a layout viewed in the direction (the Z-axis direction) from the second surface (the back surface) of the substrate toward the first surface (the front surface) thereof. In the description of FIG. 7, redundant descriptions of the same reference numerals as those in FIGS. 4 and 6 are omitted.

Referring to FIG. 7, the image sensor may include at least one of the first to sixth pixels PX1 to PX6. Each of the first to sixth pixels PX1 to PX6 may include first to fourth photodiode regions defined by the isolation layer IL including the first isolation layer and the second isolation layer, and each of the first to sixth pixels PX1 to PX6 may include first to fourth micro-lenses ML1 to ML4 arranged to correspond to the first to fourth photodiode regions, respectively. For example, the first micro-lens ML1 may be arranged on the first photodiode region, the second micro-lens ML2 may be arranged on the second photodiode region, the third micro-lens ML3 may be arranged on the third photodiode region, and the fourth micro-lens ML4 may be arranged on the fourth photodiode region. Each of the first to fourth micro-lenses ML1 to ML4 may focus and provide incident light to a corresponding photodiode region among the first to fourth photodiode regions.

Each of the first to sixth pixels PX1 to PX6 may include first to fourth backside scattering structures arranged to respectively correspond to the centers of the first to fourth micro-lenses ML1 to ML4. For example, the first backside scattering structure corresponding to the center of the first micro-lens ML1 may be arranged inside or on the first photodiode region, the second backside scattering structure corresponding to the center of the second micro-lens ML2 may be arranged inside or on the second photodiode region, the third backside scattering structure corresponding to the center of the third micro-lens ML3 may be arranged inside or on the third photodiode region, and the fourth backside scattering structure corresponding to the center of the fourth micro-lens ML4 may be arranged inside or on the fourth photodiode region. Each of the first to fourth backside scattering structures included in each of the first to sixth pixels PX1 to PX6 may be an ‘x’-shaped backside scattering structure BST or a ‘+’-shaped backside scattering structure BSTa.

Each of the first pixel PX1, the second pixel PX2, the fourth pixel PX4, and the fifth pixel PX5 may further include a fifth backside scattering structure disposed at the center of the first to fourth photodiode regions. The second isolation layer that extends to protrude from the first isolation layer may be formed to expose the center of the first to fourth photodiode regions. The fifth backside scattering structure may be arranged in a central region of the first to fourth photodiode regions (i.e., a region in which the first to fourth photodiode regions contact one another) in which the isolation layer IL is not formed.

The fifth backside scattering structure may be formed inside the first to fourth photodiode regions or may be formed as a prism structure on the second surface of the first to fourth photodiode regions. The fifth backside scattering structure may be an ‘x’ shaped backside scattering structure BST or a ‘+’ shaped backside scattering structure BSTa.

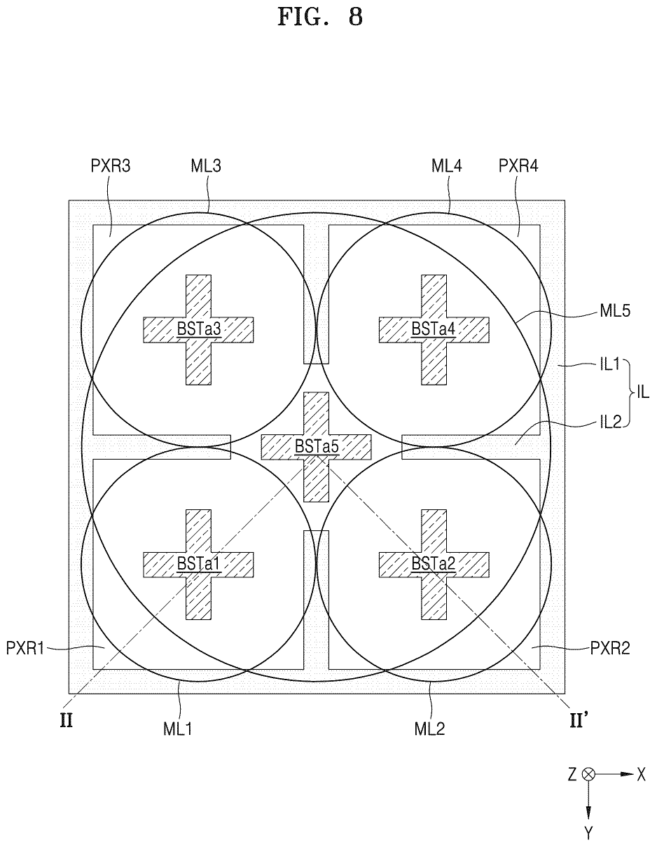

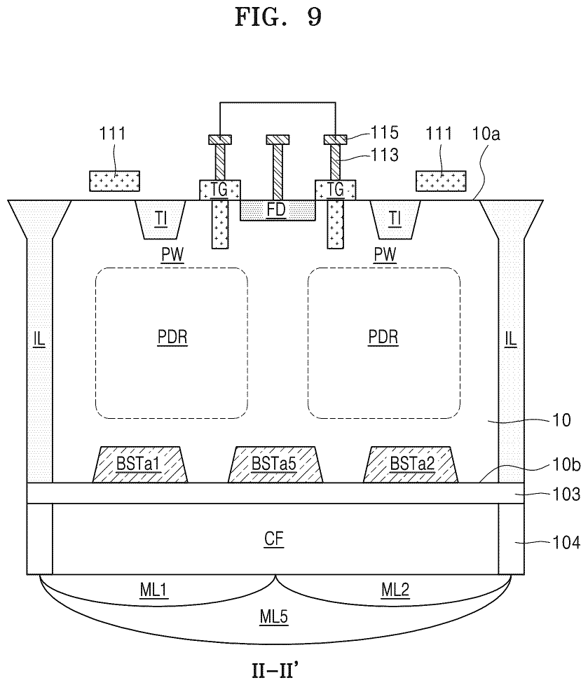

FIGS. 8 and 9 are diagrams of pixels included in an image sensor according to embodiments. FIG. 8 is a layout viewed in the direction (the Z-axis direction) from the second surface (the rear surface) of the substrate toward the first surface (the front surface) thereof, and FIG. 9 is a cross-sectional view taken along line II-II′ of FIG. 8. In the description of FIGS. 8 and 9, redundant descriptions of the same reference numerals as those in FIGS. 4, 5A, and 6 are omitted.

Referring to FIGS. 8 and 9, the pixels of the image sensor may include first to fourth backside scattering structures BSTa1 to BSTa4 respectively corresponding to first to fourth photodiode regions PXR1 to PXR4 and may further include a fifth backside scattering structure BSTa5 disposed at the center of the first to fourth photodiode regions PXR1 to PXR4. The second isolation layer IL2 that extends to protrude from the first isolation layer IL1 may be formed to expose the center of the first to fourth photodiode regions PXR1 to PXR4, and the fifth backside scattering structure BSTa5 may be arranged at the center of the first to fourth photodiode regions PXR1 to PXR4.

As illustrated in FIG. 9, each of the first to fifth backside scattering structures BSTa1 to BSTa5 may be formed inside the substrate 10 on which the first to fourth photodiode regions PXR1 to PXR4 are formed or may be formed as a prism structure on the second surface 10b of the first to fourth photodiode regions PXR1 to PXR4 as illustrated in FIG. 5B. In FIG. 8, each of the first to fifth backside scattering structures BSTa1 to BSTa5 is illustrated as a ‘+’-shaped backside scattering structure, but the disclosed concepts is not limited thereto, and may also be an ‘x’-shaped scattering structure.

The pixels of the image sensor may include first to fourth micro-lenses ML1 to ML4 respectively corresponding to first to fourth photodiode regions PXR1 to PXR4 and may further include a fifth micro-lens ML5 placed on the first to fourth micro-lenses ML1 to ML4. In embodiments, the first to fourth micro-lenses ML1 to ML4 may be arranged on the same plane, and the fifth micro-lens ML5 may be arranged on the first to fourth micro-lenses ML1 to ML4. For example, the first to fifth micro-lenses ML1 to ML5 may be manufactured through a process of forming the first to fourth micro-lenses ML1 to ML4 and then additionally forming the fifth micro-lens ML5 on the first to fourth micro-lenses ML1 to ML4.

The first to fourth backside scattering structures BSTa1 to BSTa4 may be arranged to correspond to the centers of the first to fourth micro-lenses ML1 to ML4, respectively. The fifth backside scattering structure BSTa5 may be positioned to correspond to the center of the fifth micro-lens ML5. Accordingly, each of the first to fourth micro-lenses ML1 to ML4 may focus and provide incident light to the first to fourth backside scattering structures BSTa1 to BSTa4, and the fifth micro-lens ML5 may focus and provide incident light to the fifth backside scattering structure BSTa5.

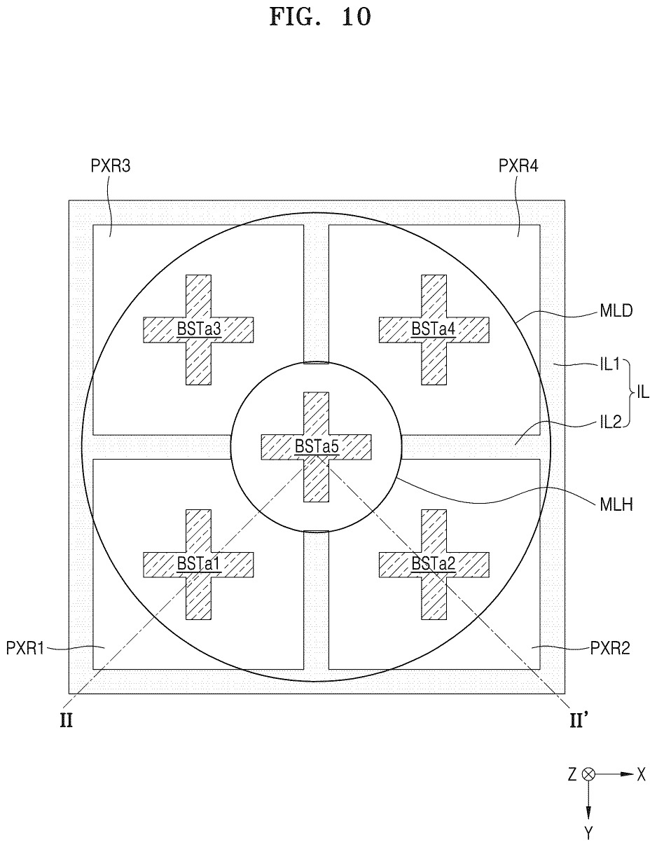

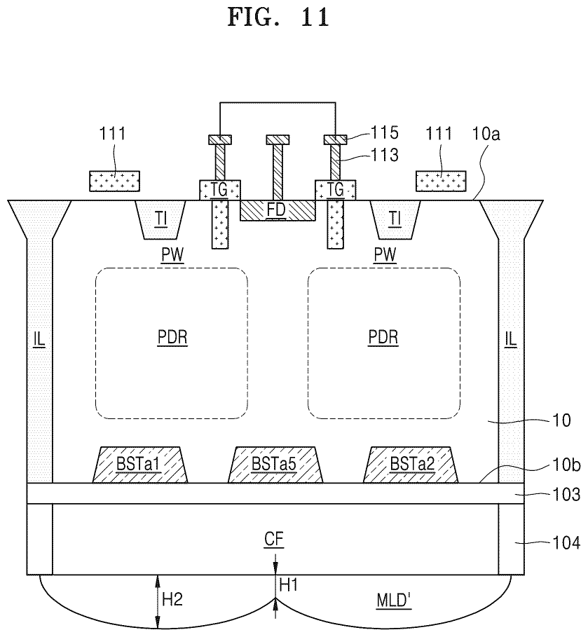

FIGS. 10 and 11 are diagrams of pixels included in an image sensor according to embodiments. FIG. 10 is a layout viewed in the direction (the Z-axis direction) from the second surface (the rear surface) of the substrate toward the first surface (front surface) thereof, and FIG. 11 is a cross-sectional view of a pixel cut in the vertical direction (the Z-axis direction). In the description of FIGS. 10 and 11, redundant descriptions of the same reference numerals as those in the previous drawings are omitted.

Referring to FIGS. 10 and 11, the pixels of the image sensor may include donut-shaped micro-lenses MLDs arranged on the first to fourth photodiode regions PXR1 to PXR4. For example, the micro-lens MLD may include a hole MLH formed in a central region, and the central regions of the first to fourth photodiode regions PXR1 to PXR4 may be exposed by the hole MLH.

Alternatively, the pixels of the image sensor may include micro-lenses MLD′ arranged on the first to fourth photodiode regions PXR1 to PXR4, and even if the micro-lenses MLD′ do not include the hole MLH formed in the central region, a first height H1 of the central region may be lower than a second height H2 of the other regions. Therefore, the donut-shaped micro-lens MLD of FIG. 9 or the micro-lens MLD′ of FIG. 11 may have a lower maximum height compared to other micro-lenses, and the cost of manufacturing the micro-lens MLD or MLD′ may be reduced.

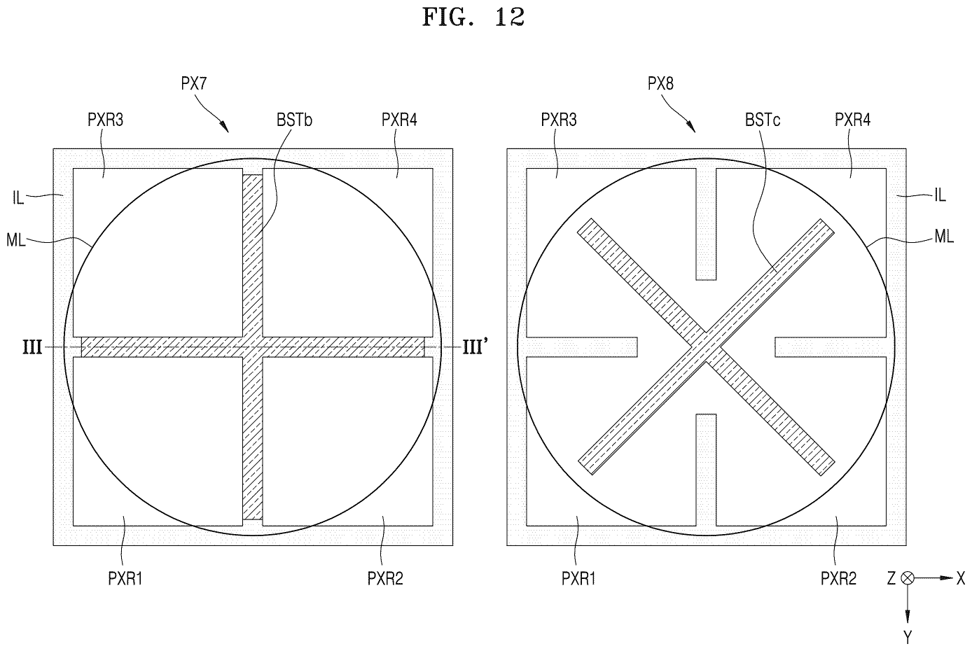

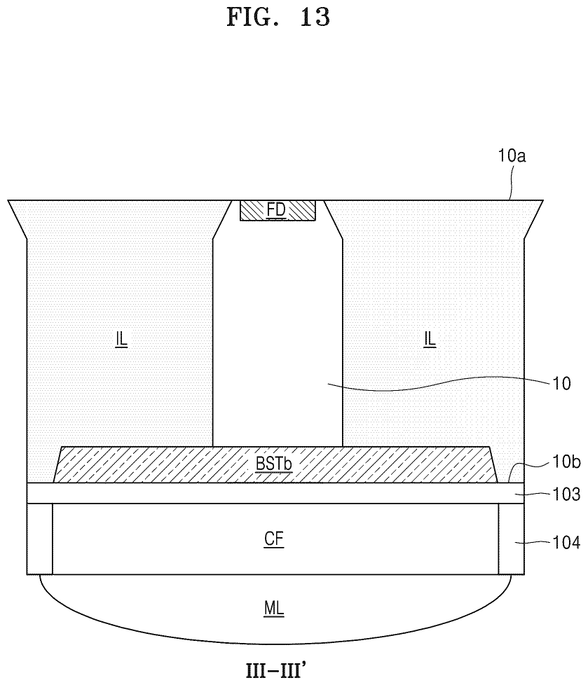

FIGS. 12 and 13 are diagrams of pixels included in an image sensor according to embodiments. FIG. 12 is a layout viewed in the direction (the Z-axis direction) from the second surface (the rear surface) of the substrate toward the first surface (the front surface) thereof, and FIG. 13 is a cross-sectional view taken along line III-III′ of FIG. 12. In the description of FIGS. 12 and 13, redundant descriptions of the same reference numerals as those in the previous drawings are omitted.

Referring to FIG. 12, the image sensor may include a seventh pixel PX7 or an eighth pixel PX8. The seventh pixel PX7 and the eighth pixel PX8 may include a backside scattering structure BSTb or BSTc including patterns that are relatively long compared to the pixels described above with reference to FIG. 4 or 6.

Referring to FIGS. 12 and 13, the backside scattering structure BSTb of the seventh pixel PX7 may have a ‘+’ shape and may include a first pattern extending in the X-axis direction and a second pattern extending in the Y-axis direction. The backside scattering structure BSTb may be formed to be in contact with the isolation layer IL, for example, the second isolation layer.

For example, a deep trench may be formed from the first surface 10a of a substrate 10 toward the second surface 10b thereof to form the isolation layer IL, and then a trench may be formed in the second surface 10b of the substrate to form the backside scattering structure BSTb. A portion of the isolation layer IL may also be etched to form a trench for forming the backside scattering structure BSTb in the second surface 10b of the substrate, and the backside scattering structure BSTb may be formed to be in contact with the isolation layer IL. Alternatively, the backside scattering structure BSTb may be formed between the anti-reflective layer 103 and the color filter CF to overlap the isolation layer IL in the Z-axis direction.

Referring back to FIG. 12, the backside scattering structure BSTc of the eighth pixel PX8 may have an ‘X’ shape. The backside scattering structure BSTc may include a first pattern and a second pattern extending in the horizontal direction of the substrate (e.g., 10 in FIG. 5A) into the first to fourth photodiode regions PXR1 to PXR4. For example, the backside scattering structure BSTc may have the first pattern and the second pattern extending to overlap the photoelectric conversion region (e.g., PDR of FIG. 5A) formed inside the substrate 10 in the Z-axis direction.

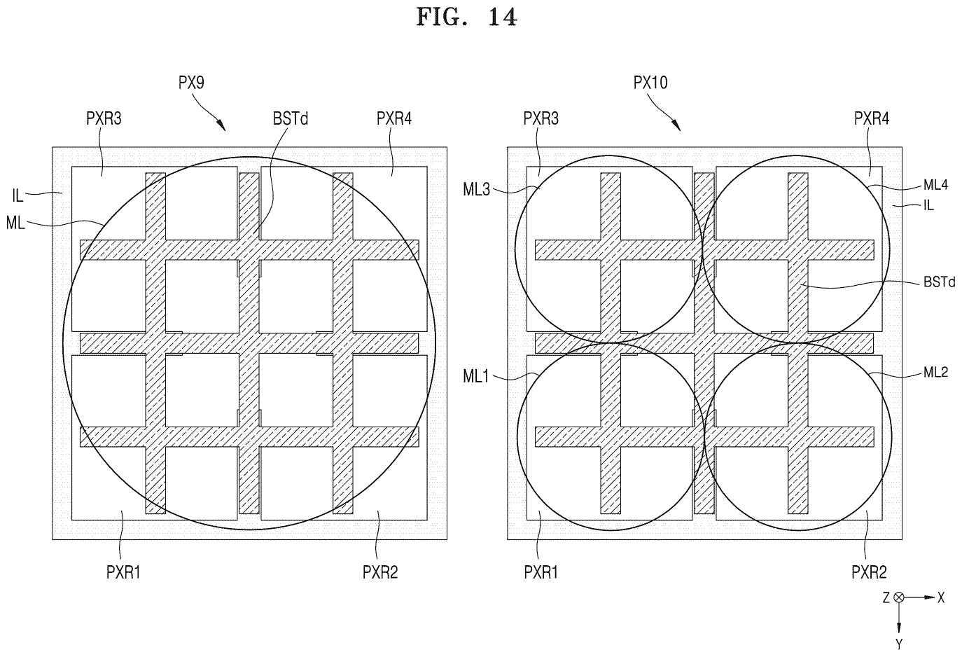

FIG. 14 is a diagram of pixels included in an image sensor according to embodiments. FIG. 14 is a layout viewed in a direction (the Z-axis direction) from the second surface (the rear surface) of the substrate toward the first surface (the front surface) thereof.

Referring to FIG. 14, the image sensor may include a ninth pixel PX9 or a tenth pixel PX10. The ninth pixel PX9 or the tenth pixel PX10 may include a backside scattering structure BSTd having a lattice (or mesh) pattern. For example, the backside scattering structure BSTd of the ninth pixel PX9 and the tenth pixel PX10 may include a plurality of first patterns extending in the X-axis direction (the first horizontal direction) and a plurality of second patterns extending in the Y-Attorney axis direction (the second horizontal direction). Alternatively, for example, the backside scattering structure BSTd of the ninth pixel PX9 and the tenth pixel PX10 may include a plurality of first patterns extending in a third horizontal direction and a plurality of second patterns extending in a fourth horizontal direction, and the third horizontal direction and the fourth horizontal direction may refer to diagonal directions between the X-axis direction and the Y-axis direction.

In embodiments, the backside scattering structure BSTd may be formed to contact the isolation layer IL, for example, the second isolation layer. For example, a deep trench may be formed from the first surface (e.g., 10a of FIG. 5A) of the substrate (e.g., 10 of FIG. 5A) toward the second surface (e.g., 10b of FIG. 5A) thereof to form the isolation layer IL, and a trench may be formed in the second surface 10b of the substrate 10 to form the backside scattering structure BSTd. Alternatively, in embodiments, the backside scattering structure BSTd may be formed between the anti-reflective layer (e.g., 130 in FIG. 5A) and the color filter (e.g., CF in FIG. 5A) to overlap the isolation layer IL in the Z-direction.

The ninth pixel PX9 may include one micro-lens ML arranged on the first to fourth photodiode regions PXR1 to PXR4. Here, the ninth pixel PX9 may include a donut-shaped micro-lens ML.

The tenth pixel PX10 may include first to fourth micro-lenses ML1 to ML4 arranged to correspond to the first to fourth photodiode regions PXR1 to PXR4, respectively. The tenth pixel PX10 may further include a fifth micro-lens disposed on the first to fourth micro-lenses ML1 to ML4.

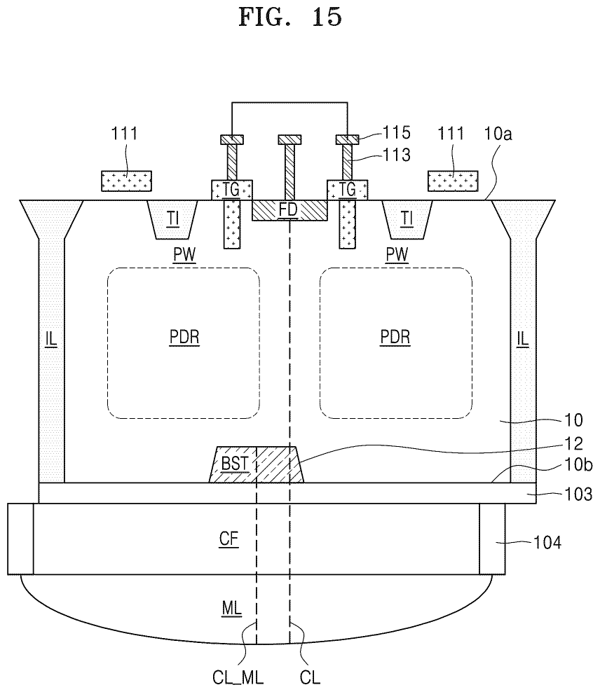

FIG. 15 is a diagram of pixels included in an image sensor according to embodiments. FIG. 15 is a cross-sectional view of an edge pixel included in a pixel array taken in the vertical direction (the Z-axis direction).

Referring to FIG. 1 and FIG. 15, the pixel array 110 of the image sensor 100 may include a plurality of pixels arranged in the central region of the pixel array 110 and a plurality of pixels (i.e., edge pixels) arranged in the edge region surrounding the central region. Depending on the characteristics of the pixel arrangement in the pixel array 110, the edge pixels arranged in the edge region of the pixel array 110 may be arranged such that the micro-lens ML is biased in one direction with respect to a center line CL of the edge pixels in order to focus incident light onto the photoelectric conversion region PDR. That is, the center line CL of the edge pixel may be misaligned with the center line CL_ML of the micro-lens ML.

The edge pixel may include the backside scattering structure BST, and the backside scattering structure BST may be positioned to correspond to the center line CL_ML of the micro-lens ML. Depending on the arrangement characteristics of the micro-lens ML at the edge pixels, the backside scattering structure BST may be arranged to be misaligned with the center line CL of the edge pixels. The backside scattering structure BST of the edge pixel may be formed in the trench 12 formed in the second surface 10b of the substrate 10 or may be formed between the anti-reflective layer 103 and the color filter CF.

In addition, pixels arranged in the central region of the pixel array 110 may have a cross-sectional structure as shown in FIGS. 5A, 5B, 9, 11, or 13.

According to aspects of the disclosed concepts, there is provided a method for manufacturing an image sensor including providing a substrate including first to fourth photodiode regions in which a photodiode is respectively formed, forming a first isolation layer to surround the first to fourth photodiode regions and penetrate from a first surface of the substrate to a second surface of the substrate that is opposite to the first surface, forming a second isolation layer to protrude from the first isolation layer and separate the first to fourth photodiode regions, forming a floating diffusion region on the first surface and in which photocharges generated in the photodiode of each of the first to fourth photodiode regions accumulate, forming at least one backside scattering structure inside a trench formed on the second surface of the substrate, and placing at least one micro-lens on the second surface of the substrate, wherein respective gates of first to fourth transfer transistors are electrically connected to one another, the second isolation layer is formed to expose a central region of the first to fourth photodiode regions, and the floating diffusion region is arranged in the central region of the first to fourth photodiode regions.

While the disclosed concepts has been particularly shown and described with reference to embodiments thereof, it will be understood that various changes in form and details may be made therein without departing from the spirit and scope of the following claims.

What is claimed is:

1. An image sensor comprising:
a substrate including first to fourth photodiode regions in which a photodiode is respectively formed;
a first isolation layer formed to surround the first to fourth photodiode regions and penetrating from a first surface of the substrate to a second surface of the substrate that is opposite to the first surface;
a second isolation layer formed to protrude from the first isolation layer and separating the first to fourth photodiode regions;
a floating diffusion region formed on the first surface of the substrate and in which photocharges generated in the photodiode of each of the first to fourth photodiode regions accumulate;
at least one backside scattering structure formed inside a trench formed in the second surface of the substrate; and
at least one micro-lens placed on the second surface of the substrate,
wherein:
respective gates of first to fourth transfer transistors are electrically connected to one another,
the second isolation layer is formed to expose a central region of the first to fourth photodiode regions, and
the floating diffusion region is arranged in the central region of the first to fourth photodiode regions.

2. The image sensor of claim 1, wherein:
the second isolation layer is formed to penetrate from the first isolation layer in a first horizontal direction and a second horizontal direction,
the at least one backside scattering structure is formed such that a first pattern extending in a third horizontal direction intersects a second pattern extending in a fourth horizontal direction, and
the third horizontal direction and the fourth horizontal direction are diagonal directions between the first horizontal direction and the second horizontal direction.

3. The image sensor of claim 2, wherein:
the second isolation layer is formed to penetrate from the first isolation layer in the first horizontal direction and the second horizontal direction, and
the at least one backside scattering structure is formed such that a first pattern extending in the first horizontal direction intersects a second pattern extending in the second horizontal direction.

4. The image sensor of claim 1, wherein:
the at least one micro-lens includes first to fourth micro-lenses arranged to correspond to the first to fourth photodiode regions, respectively, and
the at least one backside scattering structure includes first to fourth backside scattering structures arranged to correspond to respective centers of the first to fourth micro-lenses.

5. The image sensor of claim 4, wherein the at least one backside scattering structure further includes a fifth backside scattering structure disposed at a center of the first to fourth photodiode regions.

6. The image sensor of claim 4, wherein the at least one micro-lens further includes a fifth micro-lens disposed on the first to fourth micro-lenses.

7. The image sensor of claim 1, wherein at least one micro-lens has a central region having a lower height than other regions.

8. The image sensor of claim 1, wherein the at least one backside scattering structure includes a plurality of line patterns forming a lattice structure.

9. The image sensor of claim 1, wherein:
a pixel array including a plurality of pixels arranged in a central region and a plurality of pixels arranged in an edge region surrounding the central region is included,
the first to fourth photodiode regions may be included in one pixel among a plurality of pixels arranged in the edge region,
the at least one micro-lens includes one micro-lens arranged on the first to fourth photodiode regions and arranged to be offset from a center of the first to fourth photodiode regions, and
the at least one backside scattering structure includes a backside scattering structure arranged to correspond to a center of the one micro-lens.

10. The image sensor of claim 1, further comprising:
first to fourth transfer transistors transferring photocharges generated in the photodiode of each of the first to fourth photodiode regions to the floating diffusion region,
wherein the first to fourth transfer transistors include a plurality of gate patterns.

11. An image sensor comprising:
a substrate including first to fourth photodiode regions in which photodiode is respectively formed;
an isolation layer separating the first to fourth photodiode regions and penetrating from a first surface of the substrate to a second surface of the substrate that is opposite to the first surface;
a floating diffusion region formed on the first surface and in which photocharges generated in the photodiode of each of the first to fourth photodiode regions accumulate;
first to fourth transfer transistors transferring photocharges generated in the photodiode of each of the first to fourth photodiode regions to the floating diffusion region;
at least one micro-lens placed on the second surface of the substrate; and
at least one backside scattering structure formed inside a trench formed in the second surface of the substrate and positioned to correspond to a center of the at least one micro-lens,
wherein respective gates of the first to fourth transfer transistors are electrically connected to one another.

12. The image sensor of claim 11, further comprising an anti-reflective layer and a color filter layer located between the substrate and the at least one micro-lens.

13. The image sensor of claim 11, wherein:
the isolation layer is formed to extend in a first horizontal direction and a second horizontal direction,
the at least one backside scattering structure is formed such that a first pattern extending in a third horizontal direction intersects a second pattern extending in a fourth horizontal direction, and
the third horizontal direction and the fourth horizontal direction are diagonal directions between the first horizontal direction and the second horizontal direction.

14. The image sensor of claim 13, wherein:
the isolation layer is formed to extend in the first horizontal direction and the second horizontal direction, and
the at least one backside scattering structure is formed such that a first pattern extending in the first horizontal direction intersects a second pattern extending in the second horizontal direction.

15. The image sensor of claim 11, wherein:
the at least one micro-lens includes first to fourth micro-lenses arranged to correspond to the first to fourth photodiode regions, respectively, and
the at least one backside scattering structure includes first to fourth backside scattering structures arranged to correspond to a center of each of the first to fourth micro-lenses.

16. The image sensor of claim 15, wherein the at least one micro-lens further includes a fifth micro-lens placed on the first to fourth micro-lenses.

17. The image sensor of claim 15, wherein the at least one backside scattering structure further includes a fifth backside scattering structure placed at a center of the first to fourth photodiode regions.

18. An image sensor comprising:
a substrate including first to fourth photodiode regions in which photodiode is respectively formed;
an isolation layer separating the first to fourth photodiode regions and penetrating from a first surface of the substrate to a second surface of the substrate that is opposite to the first surface;
a floating diffusion region formed on the first surface and in which photocharges generated in the photodiode of each of the first to fourth photodiode regions accumulate;
first to fourth transfer transistors transferring photocharges generated in the photodiode of each of the first to fourth photodiode regions to the floating diffusion region;
a color filter layer and a micro-lens arranged on the second surface of the substrate; and
a backside scattering structure placed between the substrate and the color filter layer on the second surface of the substrate,
wherein respective gates of the first to fourth transfer transistors are electrically connected to one another.

19. The image sensor of claim 18, further comprising:
an anti-reflective layer located between the substrate and the color filter layer,
wherein the backside scattering structure is located between the anti-reflective layer and the color filter layer.

20. The image sensor of claim 18, wherein the backside scattering structure includes a material having a higher refractive index than that of the color filter layer.
